(19) United States
(12) Patent Application Publication
(10) Pub. No.: US 2006/0237338 A1
(43) Pub. Date: Oct. 26, 2006

(54) Substrate containing case

(75) Inventor: Satoshi Nakamae, Tokyo-To (JP)

Correspondence Address: OLIFF & BERRIDGE, PLC, P.O. BOX 19928, ALEXANDRIA, VA, 22320, US

(73) Assignee: DAI NIPPON PRINTING CO., LTD., Tokyo (JP)

(21) Appl. No.: 10/568,580

(22) PCT Filed: Sep. 15, 2004
(86) PCT No.: PCT/JP04/13430

§ 371 Date: Feb. 17, 2006

(30) Foreign Application Priority Data
Sep. 16, 2003 (JP) 2003-323585

(51) Int. Cl. G03F 9/00

(52) U.S. Cl. 206/316.1

(57) ABSTRACT

A substrate containing case having an upper cover and a lower cover coupled to each other through hinges such that they can be opened/closed freely. Upper and lower supporting part of a substrate are provided at four corners of the upper and lower covers, projecting from the inner surfaces of the covers. The lower supporting part of the lower cover serves to position and support simultaneously two edges at each corner of the substrate on the lower surface side. When the upper cover is closed, two edges at each corner of the substrate on the upper surface side are secured by the upper supporting part of the upper cover, and thus the substrate is contained.

### BACKGROUND OF THE INVENTION

1. Field of the Invention

The present invention relates to a substrate storage case for storing and carrying a substrate such as a photo mask or a photo mask blank used for manufacturing a semiconductor element or a liquid crystal display element, and in particular, to a substrate storage case for storing and carrying substrates one by one, which can store and carry even a photo mask with a pellicle.

2. The Related Art of the Invention

In a conventional substrate storage case for storing and carrying substrates one by one, for example, a main body and a lid body are connected through a hinge, a fixing member is provided on each inner surface of the main body and the lid member to fix a stored article, outer faces of portions where the main body and the lid body are jointed are adapted to be flush with each other, and the hinge and an engagement portion thereof are arranged at a position lower than the jointing portions (for example, refer to Japanese Examined Utility Model Publication No. 6-30686). And there is known a storage case provided with a case main body, a lid body, and a lid-fixing band to block rocking of a substrate in the upper, lower, and longitudinal directions by support projections such as pins opposed to each other, each provided on each surface of the case main body and the lid body, and a surrounding piece provided on the case main body (refer to Japanese Unexamined Patent Publication No. 10-142773).

The substrate storage case described in Japanese Examined Utility Model Publication No. 6-30686) has, however, the problem that when the lid body is opened, a photo mask or the like is lifted together with the main body, so that contaminants caught therein easily attach to the photo mask or the like, thereby producing defects in appearance, and further, the problem that since a support of the photo mask in the upper and lower directions is performed by directly holding a mask front face and a mask back face with a columnar projection provided in a support member, the substrate is contaminated.

The substrate storage case described in Japanese Unexamined Patent Publication No. 10-142773 has the problem that since a front face and a back face of a substrate such as a photo mask is directly held and supported with a support projection made of plastic, the substrate is contaminated or the support projections such as the pins are damaged.

Recent miniaturization and high density in a pattern of a photo mask or the like cause an increasing demand for high quality thereof, resulting in a strong demand for properties such as low generation of dusts, damage prevention, contamination prevention, and ease of use even in a substrate storage case for the photo mask or the like.

As described above, the positioning and the supporting of the substrate in the conventional storage case are carried out individually, therefore easily generating dusts, which causes the difficulty of maintaining the high quality of the substrate.

### SUMMARY OF THE INVENTION

The present invention, from the foregoing problems, has an object of providing an inexpensive substrate storage case with cleaning and drying characteristics thereto, which stores therein a substrate such as a photo mask, wherein the substrate storage case prevents substrate damage during the storing and carrying thereof and substrate contamination due to dust generation inside the case, is easy to handle, and restricts the dust generation in putting in and taking out the substrate.

In order to solve the foregoing problems, a substrate storage case of the present invention is structured in such a manner that positioning and supporting of a substrate are carried out at the same time.

The present invention is provided with a substrate storage case for storing therein a substrate with a top face and a bottom face and having a shape corresponding to the substrate, the substrate storage case including a bottom lid, and a top lid connected through a hinge to the bottom lid so as to open and close the bottom lid and forming an engagement part between the bottom lid and the top lid, wherein lower support parts are disposed in a plurality of positions of the bottom lid, each of the lower support parts being brought in contact with a pair of edges of the substrate on a bottom face side thereof, and upper support portions are disposed in a plurality of positions of the top lid, each of the upper support parts being brought in contact with a pair of edges of the substrate on a top face side thereof.

The present invention is provided with the substrate storage case, wherein each of the substrate and the substrate storage case may be preferably formed in a square shape.

The present invention is provided with the substrate storage case, wherein each of the lower support parts and the upper support parts may preferably include a pair of support portions in contact with the pair of the edges.

The present invention is provided with the substrate storage case, wherein each of the pair of the support portions in each of the lower support parts and the upper support parts may preferably include an oblique face in contact with the edge.

The present invention is provided with the substrate storage case, wherein the lower support parts of the bottom lid and the upper support parts of the top lid may be preferably positioned symmetrically with each other and have shapes symmetrical with each other.

The present invention is provided with the substrate storage case, which may preferably further include a lock part disposed on a side of the bottom lid lower than a center in the thickness direction of the case to lock the bottom lid and the top lid, wherein the hinge is positioned on a side of the top lid higher than the center in the thickness direction of the case.

The present invention is provided with the substrate storage case, wherein the engagement part between the bottom lid and the top lid may preferably extend obliquely and downwards from the hinge toward the lock part, and a space may be preferably formed under the substrate on a side of the lock part of the bottom lid to insert a finger of an automatic transport arm.

The present invention is provided with the substrate storage case including a step portion which may be preferably provided in an outer face of each of four corners in each of the bottom lid and the top lid, the step portion being configured to come down from the other part.

The present invention is provided with the substrate storage case which may preferably further include a clamp member provided between the step portion of the bottom lid and the step portion of the top lid corresponding to the step portion of the bottom lid, wherein the clamp member clamps and also stands the bottom lid and the top lid.

The present invention is provided with the substrate storage case, wherein concave and convex portions in the bottom lid and the top lid may preferably have round shapes.

The present invention is provided with the substrate storage case, wherein each of the bottom lid and the top lid may be preferably formed of conductive plastic.

The present invention is provided with the substrate storage case, wherein each of the lower support parts may be preferably formed integrally with the bottom lid, and each of the upper support parts may be preferably formed integrally with the top lid.

According to a substrate storage case of the present invention, the positioning and the supporting of the substrate are carried out at the same time by two edges each on the top face side and on the bottom face side of each of the four corners in the substrate, whereby a front face and a back face of the substrate such as a photo mask are not directly held down, so that substrate damage or substrate contamination due to dust generation inside the case during the storing and the carrying thereof is prevented.

And when the top lid is opened, the bottom lid on which the substrate is placed is not lifted with the top lid, and dust generation in putting in and taking out the substrate is restricted, thereby providing an effect of excellent cleaning and drying characteristics in regard to the case itself.

Further, the lower support parts and the upper support parts of the substrate are respectively formed integrally with the bottom lid and the top lid, thereby reinforcing rigidity in the lower support parts and the upper support parts and preventing failures thereof. As a result, damage to and contamination of the substrate due to the failures of the support parts are prevented. And the lower support parts on the bottom lid are symmetrical with the upper support parts on the top lid, thereby easily forming the storage case and providing an inexpensive substrate storage case.

### BRIEF DESCRIPTION OF THE DRAWINGS

FIG. 1 is a plan view showing a state where a substrate storage case is opened in a first preferred embodiment of the present invention.

FIG. 2 is a side cross sectional view taken along lines A-A in the substrate storage case shown in FIG. 1.

FIG. 3 is a perspective view showing upper support parts and lower support parts on the substrate storage case in the first preferred embodiment of the present invention.

FIG. 4 is a side cross sectional view showing a state where a substrate storage case is closed in the first preferred embodiment of the present invention.

FIG. 5 is a side view showing a state where a substrate storage case is closed in the first preferred embodiment of the present invention.

FIG. 6 is a plan view showing a state where a substrate storage case is closed in a second preferred embodiment of the present invention, wherein each of four corners of the substrate storage case is thinner than an entirety thereof.

FIG. 7 is a side view showing a state where a substrate storage case is closed in the second preferred embodiment of the present invention, wherein each of four corners of the substrate storage case is thinner than an entirety thereof.

FIG. 8 is a plan view showing a state where each of the four corners of the substrate storage case in FIG. 6 is clamped by a clamp member.

FIG. 9 is a side view showing a state where each of the four corners of the substrate storage case in FIG. 7 is clamped by the clamp member which funetions as a case stand, and the substrate storage case is placed vertically.

### DETAILED DESCRIPTION OF THE PREFERRED EMBODIMENTS

Preferred embodiments of the present invention will be explained with reference to the drawings as follows.

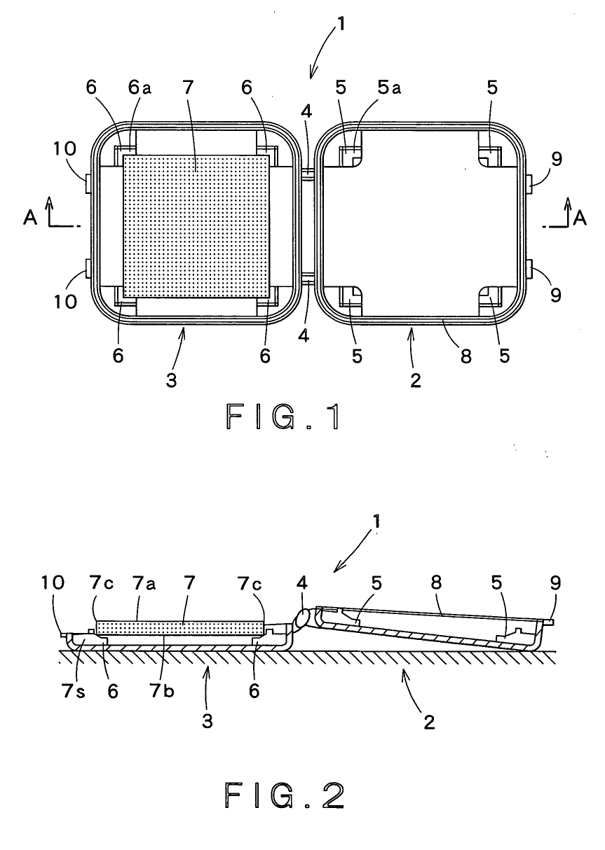

FIG. 1 is a plan view showing a state where a substrate storage case 1 is opened in a first preferred embodiment of the present invention, and FIG. 2 is a side cross sectional view taken along lines A-A in the substrate storage case shown in FIG. 1.

As shown in FIGS. 1 and 2, a substrate storage case 1 stores therein a polygonal (quadrangular) substrate 7 having a top face 7a and a bottom face 7b, and has a polygonal (quadrangular) shape corresponding to the substrate 7. The substrate storage case 1 is provided with a bottom lid 3 and a top lid 2 connected through a hinge 4 to the bottom lid 3, and is provided with an engagement portion 13 formed between the bottom lid 3 and the top lid 2.

The substrate 7 has four edges 7c on the top face 7a and four edges 7c on the bottom face 7b.

The substrate 7 stored in the substrate storage case 1 of the present invention is a substrate such as a photo mask (to be also referred to as reticle) or a photo mask blank used for manufacturing a semiconductor element or a liquid crystal display element, and a substrate made mainly of low thermal expansion glass or silica glass with a light shielding film. A main face provided typically with the light shielding film or a pattern has a square shape. A profile dimension of the substrate is defined by the standard. With regard to the substrate 7 in the present invention, a substrate with pellicle may be stored by thickening the storage case 1.

As described above, the top lid 2 and the bottom lid 3 are connected with each other through the hinge 4 so as to be opened and closed. The hinge 4 of the present invention is detachable. Therefore, the top lid 2 can be easily removed from the bottom lid 3 through the hinge 4 by opening the top lid 2 with respect to the bottom lid 3 at approximately 270 degrees. The substrate storage case 1 is so configured that the top lid 2 is easily mounted to the bottom lid 3 again through the hinge 4 at the angle where the top lid 2 has been removed from the bottom lid 3 through the hinge 4. Thus it is easy to wash and dry the lids 2, 3 separately at the time of case cleansing or the like.

Each of four upper support parts 5 for substrate is provided in each of the four corners on the inner face of the top lid 2, and each of four lower support parts 6 for substrate is provided in each of the four corners on the inner face of the bottom lid 3. Each of the upper support parts 5 and the lower support parts 6 can be formed separately from the corresponding lids 2, 3, but it is preferable for accomplishing easy formation, and strength and accuracy of the support parts that each of the upper support parts 5 and the lower support parts 6 is formed integrally with the corresponding lids 2, 3.

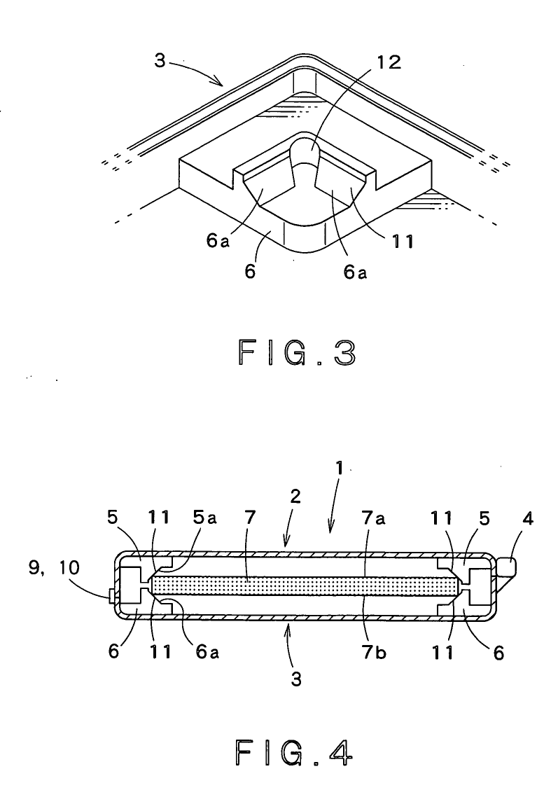

Each of the upper support parts 5 and the lower support parts 6 for the substrate is provided with a pair of support portions 5a and a pair of support portions 6a, each pair having a generally L-shape for supporting a pair of edges 7c of the substrate 7. The cross angle of each of the pair of the support portions 5a and 6a, each pair having the generally L-shape, is 90 degrees. The length of the support portion 5a is not necessarily equal to that of the support portions 6a. However, since the main face of the substrate such as the photo mask typically has a square shape, the lengths of the support portions 5a and 6a are preferably equal with each other to form the symmetry having no directness in geometry. Note that in the case of supporting a circular substrate, support portions 5a and 6a corresponding to the configuration of the circular substrate 7 are provided, thereby the same effect as that of the substrate 7 in a generally L-shape can be made. In FIG. 3, the lower support parts 6 only are shown for convenience, but the upper support parts 5 have substantially the same structure as that of the lower support parts 6.

In the present invention, each of the support portions 5a and 6a having the generally L-shape to support the substrate 7 has an oblique face and is configured so as to contact only the edge 7c on one side of the substrate 7. In FIGS. 1 and 2, the substrate 7 is placed on the support part 6 respectively in the four corners of the bottom lid 3, so that edges 7c in each of the four corners on the bottom face 7b of the substrate 7 are brought respectively in contact with two oblique faces 11 of the support portions 6a, thus the substrate 7 can be positioned and supported by the oblique faces 11 of the support portions 6a. That is, the substrate 7 is securely supported at the two neighboring edges 7c crossed to each other in each of the four corners of the bottom face 7b of the substrate 7 by the eight lower support portions 6a of the lower support parts 6.

The lower support parts 6 for the substrate 7 in the present invention will be explained in more detail. FIG. 3 is a perspective view showing one example of the lower support parts 6 on four corners of the bottom lid 3 of the substrate storage case 1.

Each of the support portions 6a supporting the edges 7c of the substrate 7 and surrounded by two sections in a L-shape has an oblique face 11. An angle of the oblique face 11 may be an angle at which the substrate 7 can be positioned and supported, which is in the range of 15 degrees to 75 degrees with respect to the bottom face of the bottom lid 3. When an angle of the oblique face 11 is less than 15 degrees, the support strength for the substrate 7 is not sufficient due to such small angle and reoccurrence of the same support position is reduced. When an angle of the oblique face 11 exceeds 75 degrees, degrees of freedom to the dimensional tolerance in size of the substrate 7 become insufficient, possibly causing in damages of the substrate 7. More preferably an angle of the oblique face is in the range of 30 degrees to 60 degrees for heightening a mechanical strength of the support part 6, support characteristics for the substrate 7, dispersion characteristics of forces applied on the substrate 7, and degrees of freedom in size of the substrate 7. Furthermore preferably, an angle of the oblique face 11 is 45 degrees so that forces applied on the substrate 7 in the vertical and longitudinal directions can become equal.

In the present invention, as shown in FIG. 3, in order to prevent contact between the substrate 7 and the substrate storage case 1 caused by deviations of the substrate 7 and to relieve stresses generated in the support portion 6a for the edge 7c of the substrate 7, a space 12 is preferably provided at a crossing point between the support portions 6a as two sides in a generally L-shape. FIG. 3 shows an example where the space 12 is provided by removing a resin in a columnar shape in the vicinity of the crossing point between the two support portions 6a in a generally L-shape.

Further, in the present invention two support portions 6a may be separated from each other and crossed at 90 degrees to form a mountain shape (formed by two unparalleled sections). However, the generally L-shape as described above is preferable for improving strength of the lower support part 6. Note that the upper support part 5 is provided in a position on the top lid 2 corresponding to the lower support part 6, and is substantially the same structure of the lower support part 6.

Next, by closing the top lid 2, two edges 7c in each of the four corners on the top face 7a of the substrate 7 can be respectively brought in contact with two oblique faces 11 of the upper support part 5 to support and clamp the substrate 7. That is, the substrate 7, as is similar to a side of the bottom face 7b, is supported and fixed on the eight support portions 5a of the upper support parts 5 at two edges crossed and neighbored in each of the four corners on the top face 7a.

FIG. 4 is a side cross sectional view showing a state where the top lid 2 is closed.

As shown in FIG. 4, the substrate 7 is clamped in such a manner that the edges 7c in the four corners on each of the top and bottom faces 7a and 7b thereof are positioned both at the oblique faces 11 provided in the support portions 5a of the upper support parts 5 on the top lid 2 and at the oblique faces 11 provided in the support portions 6a of the lower support parts 6 on the bottom lid 3, whereby at the same time, the substrate 7 is prevented from moving in the vertical and longitudinal directions. The substrate 7 does not move by vibrations generated during the shipping thereof, and as a result, the substrate 7 can not be damaged and contamination of the substrate 7 due to dust generation can not be generated.

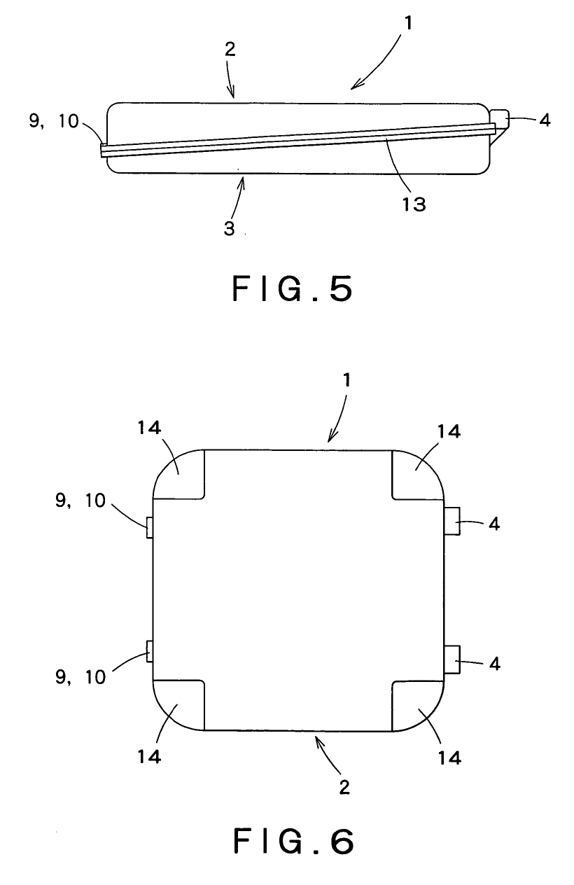

FIG. 5 is a side view showing a state where the substrate storage case in the first preferred embodiment of the present invention, is closed. As shown in FIG. 5, in the present invention the hinge 4 is provided at a position higher than a center of the thickness direction of the substrate storage case 1, and lock parts 9 and 10 to lock the top lid 2 and the bottom lid 3 are provided at a position lower than the hinge 4. Accordingly, an engagement part 13 between the top lid 2 and the bottom lid 3 of the substrate storage case 1 has an oblique part extending obliquely and downwards from the hinge 4 toward the lock parts 9 and 10.

The substrate storage case according to the present invention is so configured as described above. Thus, as shown in FIG. 2, when the top lid 2 of the substrate storage case 1 is opened, a hinge side of the bottom lid 3 is not lifted. Therefore, in the present invention, there does not occur the problem that dusts in the circumstance of the substrate storage case 1 becomes poor involved therein due to the hinge side of the bottom lid 3 being lifted or that an appearance of the substrate storage case 1 becomes poor by attachment of foreign materials to the substrate 7 like the conventional case. In the preferred embodiment shown in FIG. 2, the top lid 2 is opened at an angle of approximately 185 degrees away from a point where the top lid 2 is closed.

Further, in the present invention, the lock parts 9 and 10 are provided at a position lower than the center in the thickness direction of the substrate storage case 1 in addition to the configuration in FIG. 5 as described above. When the top lid 2 is opened, a space 7s in size large enough for a finger of an automatic transport arm to be inserted is provided under the substrate 7. As a result, when the top lid 2 is opened to take out the substrate 7 therein, the finger of the automatic transport arm can be inserted under the substrate 7, and therefore the substrate 7 in the substrate storage case 1 can be putted in or taken out without aid of persons. Further, hooks of the lock parts 9 and 10 are adapted to be opened and closed by the automatic transport arm, thereby the putting in and the taking out of the substrate 7 in the substrate storage case 1 can be automatically made, and therefore of the substrate storage case 1 can be securely transported.

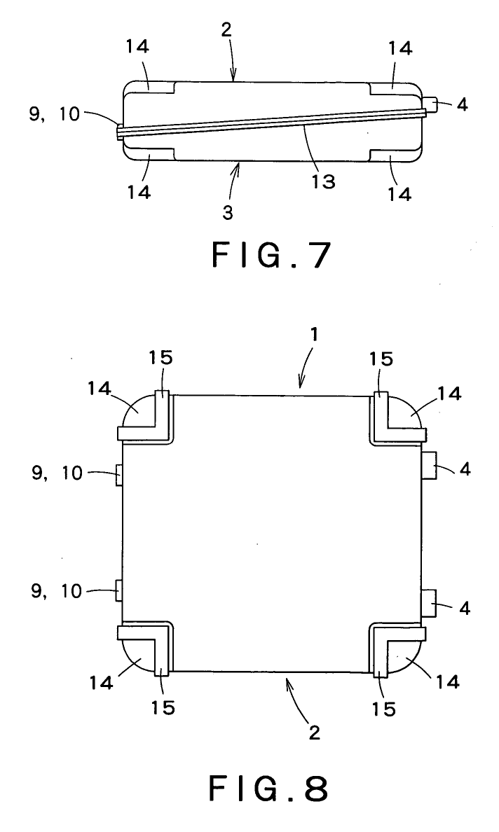

As shown in FIGS. 6 and 7, the thickness in each of the four corners in the substrate storage case 1 including the upper support parts 5 and the lower support parts 6 may be thinner than that of the entirety of the substrate storage case 1.

FIG. 6 is a plan view showing a state where a substrate storage case is closed in a second preferred embodiment of the present invention, wherein the thickness in each of the four corners of the substrate storage case 1 including the upper support parts 5 and the lower support parts 6 is thinner than that of the entirety thereof. FIG. 7 is a side view in FIG. 6. In FIGS. 6 and 7, components identical to those in FIGS. 1, 2, and 5 are referred to as identical numerals.

In FIGS. 6 and 7, a step portion 14 is formed by making an outer face of each of four corners in each of the top lid 2 and the bottom lid 3 of the substrate storage case 1 thinner. By forming the thinner outer faces in the four corners, the photo mask can be easily stored in the substrate storage case 1, and the case 1 can be securely locked. The height of each of the support parts 5 and 6 can be lowered because the four corners include the support parts 5 and 6, as a result the support parts 5, 6 can improve rigidity thereof as the support member. Since the step portion 14 is provided at the four corners, the substrate storage case 1 can be fixed, not at the outermost periphery, but at an inside of the substrate storage case 1 (closer to the support parts 5 and 6), thereby no influence of dust generation will not occur due to the apparatus.

FIG. 8 is a plan view showing a state where the four corners of the substrate storage case 1 in FIG. 6 are clamped by clamping members 15. In the present invention, the clamping members 15 are fixed to the step portions 14 provided in the four corners of the substrate storage case 1 as shown in FIG. 8, whereby it is possible to securely lock the top lid 2 and the bottom lid 3. Since the thickness in the four corners of the substrate storage case 1 is thinner, it is easy to mount and remove the clamping members 15. Furthermore, it is possible to make the thickness in the four corners including the thickness of the clamping member 15 after the mounting be within the range of the thickness of an entire substrate storage case 1. As a result, the clamping member 15 does not cause an obstacle in storing and carrying the substrate storage case 1.

The clamping member 15 may be formed of plastic, rubber, a metallic clipper, or a fixture band.

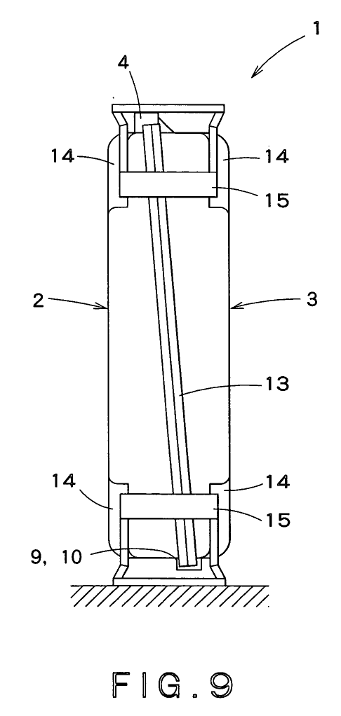

Further, FIG. 9 is a side view showing a state where each of the four corners of the substrate storage case 1 in FIG. 7 is clamped by the clamp member 15 which functions as a case stand and the substrate storage case 1 is placed vertically. The substrate storage case 1 of the present invention, as shown in FIG. 9, can be vertically arranged neatly like books in a mask storage shelf or the like by using the clamping member 15 functioning as a case stand. When an IC tag or the like is attached to an outside of the substrate storage case 1, it is possible to automatically put in and take out the substrate storage case 1 in the shelf. In addition, the substrate storage case 1 can be automatically transported and the substrate 7 can be automatically put in and taken out the substrate storage case 1. As a result, manual labors can be reduced to reduce a quality problem due to dusts, and quality and productivity of the substrate 7 can be improved, thus manufacture, transport, and storage of a high-quality mask can be accomplished.

It is preferable that a material of each of the top lid 2, the bottom lid 3, the support parts 5 and 6 is recyclable with a low dust generation, good cleansing characteristics, and good drying characteristics. When the substrate storage case 1 is charged during the shipping thereof or the like, a photo mask pattern may be destroyed due to electric discharge phenomenon or the substrate 7 may be contaminated by absorbing dusts in the air. Accordingly, it is preferable that each of the top lid 2, the bottom lid 3, the support parts 5 and 6 is made of conductive plastic. Such conductive plastic may be formed of a resin, for example, a product name “BAYON” (made by Kureha Chemical Industry Co., Ltd.) or Novalloy (made by Daicel Polymer Co., Ltd.) having a structure where rubber particles with a small electrical resistance are dispersed in the hard resin.

A gasket 8 used as packing in the engagement portion 13 between the top lid 2 and the bottom lid 3 may be formed of fluorinated rubber, for example, a product called Fluoroplas (made by NICHIAS Corp.).

In the present invention, the gasket 8 in a convex shape is provided on the engagement portion 13 of the top lid 2 to be engaged therein and the engagement portion 13 of the bottom lid 3 corresponding to the gasket 8 is formed in a concave shape, thereby the engagement portion can be securely sealed. Another engagement portion can be provided in an inside of the gasket 8. Accordingly, in a state where the lock parts 9 and 10 are unlocked, even if the sealing property of the gasket 8 is not maintained, the engagement portions are partly overlapped, thus preventing the foreign materials from entering an inside of the substrate storage case 1 from an outside. As a result, it is not necessary to bond the engagement portions of the top lid 2 and the bottom lid 3 with a tape after storing the substrate 1 into the substrate storage case 1 like the conventional storage case.

In the present invention, the gasket 8 also serves as a buffer material when the top lid 2 is put on top of the bottom lid 3.

The substrate storage case 1 according to the present invention is so structured that the top lid 2 and the bottom lid 3 are detachable from each other due to the hinge 4 and the lock parts 9 and 10 are provided and locked at one position or more. However, the substrate storage case may be so structured that, for example, the lock parts 9 and 10 are provided at two positions, and locked by a hook when the top lid 2 and the bottom lid 3 are engaged, and the lock parts 9 and 10 are unlocked by pushing the hook.

At the time of opening the top lid 2 and the bottom lid 3 of the substrate storage case 1 which has stored the substrate 7 therein, the pattern face of the substrate 7 is preferably directed downwards in order to avoid dropping and attachment of dusts to the pattern face from the surroundings. The substrate storage case 1 of the present invention may be manufactured in such a manner that the top lid 2 and the bottom lid 3 are symmetrical except for the hinge 4 and the lock parts 9 and 10. Therefore, the substrate storage case 1 can be opened from both sides of the top lid 2 and the bottom lid 3 and it is advantageous that in the inside process of a photo mask manufacture or the like, the top lid 2 and the bottom lid 3 can be optionally opened as needed.

In the substrate storage case 1 of the present invention, it is preferably to eliminate blowholes at resin molding of the storage case and to avoid generation of, dusts in corner portions and concave and convex portions. In order to accomplish the above, it is further preferable that the corner portions and the concave and convex portions have round shapes to easily wash and dry the substrate storage case 1.

Since the substrate storage case 1 of the present invention can be manufactured in such a manner that the top lid 2 and the bottom lid 3 are formed integrally with the substrate support parts 5 and 6, an inexpensive substrate storage case with high rigidity and high quality can be provided. Further, since only conductive materials are used in portions of the case which the substrate 7 is directly in contact with, it is prevented for the substrate 7 to be influenced by an extra material.

Further, the substrate storage case of the present invention is provided with a bar code label or an IC tag at an outer surface thereof and therefore, product management for each substrate storage case can be made.

### EXAMPLE 1

Next, detailed example of the above-described preferred embodiments will be explained.

In order to manufacture a substrate storage case used exclusively for a photo mask of six inches (an outside dimension: 6×6×0.25(thickness) inches), a mold for the top lid 2 and the bottom lid 3 of the case 1 (an outside dimension: 220×230×22 (thickness)mm) including the hinge 4 and the lock parts 9 and 10 was produced. The top lid 2 and the bottom lid 3, each having the resin thickness of 3 mm, were produced using Novalloy (brand name) resin (made by Daicel Polymer Ltd.). A convex engagement portion was provided at a portion of the top lid 2 where the top lid 2 and the bottom lid 3 are engaged, the convex engagement portion being as the gasket 8 made of polyester elastomer resin, and a concave engagement portion was formed at the corresponding portion of the bottom lid 3. The hinge 4 was provided in such a manner that the top lid 2 and the bottom lid 3 were detachable. The lock parts 9 and 10 were provided at two locations, whereby when the top lid 2 and the bottom lid 3 were engaged, they were locked by the hook and were unlocked by pushing the hook.

At four corners on the inner face of each of the top lid 2 and the bottom lid 3, the four support parts 5 and the four support parts 6 were respectively integral with the top lid 2 and the bottom lid 3. Each of the support parts 5 and 6 had a size of 30×30×10 (height)mm and was projected from the inner face in each of the top lid 2 and the bottom lid 3. Each of the support portions 5a and 6a in a L-shape for the substrate edge 7c, having a dimension of 20×20×20 (height from the bottom face of the lid)mm was further projected at each corner in an inside of each of the support parts 5 and 6. Each of the support parts 5 and 6 was integral with each of the top lid 2 and the bottom lid 3. Each of the support portions 5a and each of the support portions 6a for the substrate edge 7c, each surrounded by two sides in a L-shape crossed at 90 degrees, had an oblique face 11 formed at each of the two sides, and an angle of the oblique face 11 is 45 degrees to the inner face of the corresponding lid. The columnar space 12 was provided at a crossing point of the two sides in a L-shape. The top lid 2 and the bottom lid 3 were symmetrical in the upper and lower directions except for the hinge 4 and the lock parts 9 and 10 to form the substrate storage case 1.

Next, the photo mask 7 of six inches (an outside dimension: 6×6×0.25(thickness) inches) was placed on the bottom lid 3 of the storage case 1 when the above top lid 2 is opened, with the pattern face of the photo mask 7 being directed downwards. Two edges 7c on the bottom face 7b of the mask 7 in each of the four corners were respectively in contact with two oblique faces 11 of the support portion 6a, so that the mask 7 was securely positioned and supported. As a result, the mask 7 was supported on the eight oblique faces 11 of the support parts 6 by the two neighboring edges crossed vertically in each of the four corners on the bottom face 7b.

Next, the top lid 2 was closed and locked, whereby the two edges 7c in each of the four corners on the top face 7a of the mask 7 were brought in contact with the two oblique faces 11 of the support parts 5 on the top lid 2 so that the mask 7 was supported and fixed. Namely, the photo mask similarly to the bottom face 7b, was also supported and fixed securely on the eight oblique faces 11 by the two neighboring edges 7c crossed vertically in each of the four corners on the top face 7a.

### COMPARISON EXAMPLE 1

By the conventional art, the storage case (225×225×41 mm) for the photo mask of six inches was produced, the top lid and the bottom lid of which were made of BAYON resin and was able to be separated from each other. This storage case was provided with an outer periphery-fixing portion for positioning an outer periphery of the mask and a pin-shaped projection made of BAYON for fixing the mask, the fixing portion and the projection being provided in each of the top lid and the bottom lid, to support the mask. A top end of the pin-shaped projection as a contact portion with the mask was covered with silicon resin to soften the impact at the time of the contacting. The photo mask of six inches was placed on the storage case with the pattern face of the photo mask being directed downwards and fixed by the upper and lower pins. Next, the engagement portions of the top and bottom lids were sealed with wrapping tapes and clamped in the four corners by resin clips.

Comparison of Dust Generation Characteristics

A forced dust generation test was carried out in the same condition for each of the substrate storage case of the present invention in Example 1 and the conventional substrate storage case in Comparison Example 1 to compare the comparison generation characteristics. The measurement condition: a photo mask was stored in each of the substrate storage case of the present invention and the conventional substrate storage case, which thereafter, were vibrated for two hours. A size (μm) of a foreign material on each mask was measured before each mask is stored and after each mask was stored and vibrated, to compare an increased number of the foreign materials by a foreign material measurement apparatus of laser reflective type GM (made by Hitachi, Ltd.). The measurement area was 130×130 mm and an averaging value was determined by carrying out the dust generation test with regard to the four masks in each of the storage case of the present invention and the conventional storage case. As a result, it is found that an amount in the dusts generated in the storage case of the present invention is 1/7 of that in the conventional storage case.

What is claimed is:

1. A substrate storage case for storing therein a substrate with a top face and a bottom face and having a shape corresponding to the substrate, comprising:
a bottom lid; and
a top lid connected through a hinge to the bottom lid so as to open and close the bottom lid and forming an engagement part between the bottom lid and the top lid, wherein:
lower support parts are disposed in a plurality of positions of the bottom lid, each of the lower support parts being brought in contact with a pair of edges of the substrate on a bottom face side thereof; and
upper support portions are disposed in a plurality of positions of the top lid, each of the upper support parts being brought in contact with a pair of edges of the substrate on a top face side thereof.

2. The substrate storage case according to claim 1, wherein:
each of the substrate and the substrate storage case is formed in a square shape.

3. The substrate storage case according to claim 2, wherein:
each of the lower support parts and the upper support parts includes a pair of support portions in contact with the pair of the edges.

4. The substrate storage case according to claim 3, wherein:
each of the pair of the support portions in each of the lower support parts and the upper support parts includes an oblique face in contact with the edge.

5. The substrate storage case according to claim 1, wherein:
the lower support parts of the bottom lid and the upper support parts of the top lid are positioned symmetrically with each other and have shapes symmetrical with each other.

6. The substrate storage case according to claim 1, further comprising:
a lock part disposed on a side of the bottom lid lower than a center in the thickness direction of the case to lock the bottom lid and the top lid, wherein:
the hinge is positioned on a side of the top lid higher than the center in the thickness direction of the case.

7. The substrate storage case according to claim 1, wherein:
the engagement part between the bottom lid and the top lid extends obliquely and downwards from the hinge toward the lock part; and
a space is formed under the substrate on a side of the lock part of the bottom lid to insert a finger of an automatic transport arm.

8. The substrate storage case according to claim 2, wherein:
a step portion is provided in an outer face of each of four corners in each of the bottom lid and the top lid, the step portion being configured to come down from the other part.

9. The substrate storage case according to claim 8, further comprising:
a clamp member provided between the step portion of the bottom lid and the step portion of the top lid corresponding to the step portion of the bottom lid, wherein:
the clamp member clamps and also stands the bottom lid and the top lid.

10. The substrate storage case according to claim 1, wherein:
concave and convex portions in the bottom lid and the top lid have round shapes.

11. The substrate storage case according to claim 10, wherein:
each of the bottom lid and the top lid is formed of conductive plastic.

12. The substrate storage case according to claim 1, wherein:
each of the lower support parts is formed integrally with the bottom lid; and
each of the upper support parts is formed integrally with the top lid.
